(19) United States
(12) Patent Application Publication
(10) Pub. No.: US 2026/0068175 A1
(43) Pub. Date: Mar. 5, 2026

(54) MEMORY DEVICES AND FABRICATION METHODS THEREOF

(71) Applicant: Yangtze Memory Technologies Holding Co., Ltd., Wuhan (CN)

(72) Inventors: Lina Miao, Wuhan (CN); Liang Xiao, Wuhan (CN); Wenjing Xiao, Wuhan (CN); Wenbin Zhou, Wuhan (CN); Zongliang Huo, Wuhan (CN)

(73) Assignee: Yangtze Memory Technologies Holding Co., Ltd., Wuhan (CN)

(21) Appl. No.: 18/888,399

(22) Filed: Sep. 18, 2024

Related U.S. Application Data
(63) Continuation of application No. PCT/CN2024/116337, filed on Sep. 2, 2024.

(51) Int. Cl. H10B 80/00; H01L 23/00; H01L 25/00; H01L 25/065; H01L 25/18

(52) U.S. Cl. CPC H10B 80/00

(57) ABSTRACT

A memory device includes a first semiconductor chip, a second semiconductor chip, a first contact structure, and a second contact structure. The first semiconductor chip includes a first semiconductor structure and a first dielectric layer penetrating the first semiconductor structure. The second semiconductor chip stacks with the first semiconductor chip along a first direction, and the second semiconductor chip includes a second semiconductor structure and a second dielectric layer penetrating the second semiconductor structure. The first contact structure extends along the first direction in the first dielectric layer and is in contact with a first metal layer of the first semiconductor chip. The second contact structure extends along the first direction in the first dielectric layer and the second dielectric layer and is in contact with a second metal layer of the second semiconductor chip. The first dielectric layer and the second dielectric layer are aligned in the first direction.

### CROSS-REFERENCE TO RELATED APPLICATIONS

This application is a continuation of International Application No. PCT/CN2024/116337, filed on Sep. 2, 2024, which is hereby incorporated by reference in its entirety.

### BACKGROUND

The present disclosure relates to semiconductor devices and fabrication methods thereof, specifically to memory devices, memory systems, and fabrication methods thereof.

Planar memory cells are scaled to smaller sizes by improving process technology, circuit design, programming algorithm, and fabrication process. However, as feature sizes of the memory cells approach a lower limit, planar process and fabrication techniques become challenging and costly. As a result, memory density for planar memory cells approaches an upper limit.

A high bandwidth memory (HBM) uses stacked memory devices or memory chips to enable effective data movement and access. While using less power in a smaller form factor, HBM devices can achieve higher bandwidth. HBM devices have been applied to high-performance graphics accelerators, network devices, high-performance data centers, artificial intelligence (AI) and machine learning (ML) training, and various supercomputers.

### SUMMARY

According to one aspect of the present disclosure, a memory device is disclosed. The memory device includes a first semiconductor chip, a second semiconductor chip, a first contact structure, and a second contact structure. The first semiconductor chip includes a first semiconductor structure and a first dielectric layer penetrating the first semiconductor structure. The second semiconductor chip stacks with the first semiconductor chip along a first direction, and the second semiconductor chip includes a second semiconductor structure and a second dielectric layer penetrating the second semiconductor structure. The first contact structure extends along the first direction in the first dielectric layer and is in contact with a first metal layer of the first semiconductor chip. The second contact structure extends along the first direction in the first dielectric layer and the second dielectric layer and is in contact with a second metal layer of the second semiconductor chip. The first dielectric layer and the second dielectric layer are aligned in the first direction.

In some implementations, the first semiconductor chip further includes a first dielectric bonding layer, the second semiconductor chip further includes a second dielectric bonding layer, and the first semiconductor chip and the second semiconductor chip are bonded through the first dielectric bonding layer and the second dielectric bonding layer.

In some implementations, the first semiconductor structure includes a first memory structure and a first periphery structure stacking in the first direction.

In some implementations, the first memory structure is bonded to the first periphery structure through a hybrid bonding layer.

In some implementations, the hybrid bonding layer includes a dielectric bonding layer and a conductive bonding structure.

In some implementations, the first metal layer and the second metal layer extend along a second direction perpendicular to the first direction.

In some implementations, the first contact structure and the second contact structure are arranged side-by-side along the second direction.

In some implementations, a length of the second contact structure in the first direction is greater than a length of the first contact structure in the first direction.

In some implementations, a first end of the first contact structure and a first end of the second contact structure are coplanar in the second direction, a second end of the first contact structure is in contact with the first metal layer, and a second end of the second contact structure is in contact with the second metal layer.

In some implementations, the first semiconductor structure includes a first substrate and the first dielectric layer penetrates the first substrate along the first direction.

In some implementations, the first contact structure includes a first conductive layer extending in the first direction and a first glue layer covering the first conductive layer.

According to another aspect of the present disclosure, a system is disclosed. The system includes an interposer, a memory device disposed on the interposer, a base die disposed between the interposer and the memory device configured to control the memory device, and a computing die disposed on the interposer. The memory device includes a first semiconductor chip, a second semiconductor chip, a first contact structure, and a second contact structure. The first semiconductor chip includes a first semiconductor structure and a first dielectric layer penetrating the first semiconductor structure. The second semiconductor chip stacks with the first semiconductor chip along a first direction, and the second semiconductor chip includes a second semiconductor structure and a second dielectric layer penetrating the second semiconductor structure. The first contact structure extends along the first direction in the first dielectric layer and is in contact with a first metal layer of the first semiconductor chip. The second contact structure extends along the first direction in the first dielectric layer and the second dielectric layer and is in contact with a second metal layer of the second semiconductor chip. The first dielectric layer and the second dielectric layer are aligned in the first direction. The base die and the computing die are integrated on the interposer along a second direction perpendicular to the first direction.

In some implementations, the base die includes a control circuitry to control the memory device through the first contact structure and the second contact structure.

In some implementations, the base die and the computing die are bonded to a same surface of the interposer.

In some implementations, the base die is bonded to the memory device through a hybrid bonding layer.

In some implementations, the hybrid bonding layer includes a dielectric bonding layer and a conductive bonding structure.

According to a further aspect of the present disclosure, a method of forming a memory device is disclosed. A first semiconductor chip is formed. The first semiconductor chip includes a first memory structure and a first periphery structure on a first substrate, and a first dielectric structure penetrating the first substrate. A second semiconductor chip is formed. The second semiconductor chip includes a second memory structure and a second periphery structure on a second substrate, and a second dielectric structure penetrating the second substrate. The first semiconductor chip and the second semiconductor chip are bonded along a first direction. A first contact structure is formed penetrating the first dielectric structure, and a second contact structure is formed penetrating the first dielectric structure and the second dielectric structure.

In some implementations, the first semiconductor chip and the second semiconductor chip are bonded to a base die, and the base die and a computing die are bonded to an interposer.

In some implementations, a first landing layer is formed under the first dielectric structure and a second landing layer is formed under the second dielectric structure.

In some implementations, the first dielectric structure is formed on a first side of the first substrate, the first periphery structure is formed on the first side of the first substrate, the first memory structure is formed on a third substrate, the first periphery structure and the first memory structure are bonded, and a thinning operation is performed on a second side of the first substrate opposite to the first side to expose the first dielectric structure.

In some implementations, the first landing layer and a routing structure are formed on the second side of the first substrate.

In some implementations, the first periphery structure and the first memory structure are bonded through a hybrid dielectric-to-dielectric bonding and metal-to-metal bonding.

In some implementations, the first periphery structure is formed on a first side of the first substrate, the first memory structure is formed on a third substrate, the first periphery structure and the first memory structure are bonded, a thinning operation is performed on a second side of the first substrate opposite to the first side, and the first dielectric structure is formed on the second side of the first substrate penetrating the first substrate.

In some implementations, the first landing layer and a routing structure are formed on the second side of the first substrate.

In some implementations, the first periphery structure and the first memory structure are bonded through a hybrid dielectric-to-dielectric bonding and metal-to-metal bonding.

In some implementations, the first semiconductor chip and the second semiconductor chip are bonded through a direct dielectric-to-dielectric bonding.

In some implementations, the first semiconductor chip and the second semiconductor chip are bonded to have the first dielectric structure and the second dielectric structure aligned in the first direction.

In some implementations, a first opening is formed penetrating the first dielectric structure to expose the first landing layer, a second opening is formed penetrating the first dielectric structure and the second dielectric structure to expose the second landing layer, a first glue layer is formed on sidewalls of the first opening, a second glue layer is formed on sidewalls of the second opening, the first contact structure is formed in the first opening in contact with the first landing layer, and the second contact structure is formed in the second opening in contact with the second landing layer.

In some implementations, a planarization operation is performed on a top surface of the first semiconductor structure.

### BRIEF DESCRIPTION OF THE DRAWINGS

The accompanying drawings, which are incorporated herein and form a part of the specification, illustrate implementations of the present disclosure and, together with the description, further serve to explain the present disclosure and to enable a person skilled in the pertinent art to make and use the present disclosure.

FIG. 1 illustrates a schematic view of a cross-section of a memory device, according to some implementations of the present disclosure.

FIG. 2 illustrates a schematic diagram of a memory system, according to some aspects of the present disclosure.

FIGS. 3-14 illustrate cross-sectional views of an exemplary memory device at various stages of a fabrication process, according to some implementations of the present disclosure.

FIG. 15 illustrates a flowchart of a method for forming an exemplary memory device, according to some implementations of the present disclosure.

FIG. 16 illustrates a block diagram of an exemplary system having a memory device, according to some implementations of the present disclosure.

FIG. 17A illustrates a diagram of an exemplary memory card having a memory device, according to some implementations of the present disclosure.

FIG. 17B illustrates a diagram of an exemplary solid-state drive (SSD) having a memory device, according to some implementations of the present disclosure.

The present disclosure will be described with reference to the accompanying drawings.

### DETAILED DESCRIPTION

Although specific configurations and arrangements are discussed, it should be understood that this is done for illustrative purposes only. As such, other configurations and arrangements can be used without departing from the scope of the present disclosure. Also, the present disclosure can also be employed in a variety of other applications. Functional and structural features as described in the present disclosures can be combined, adjusted, and modified with one another and in ways not specifically depicted in the drawings, such that these combinations, adjustments, and modifications are within the scope of the present discloses.

In general, terminology may be understood at least in part from usage in context. For example, the term “one or more” as used herein, depending at least in part upon context, may be used to describe any feature, structure, or characteristic in a singular sense or may be used to describe combinations of features, structures or characteristics in a plural sense. Similarly, terms, such as “a,” “an,” or “the,” again, may be understood to convey a singular usage or to convey a plural usage, depending at least in part upon context. In addition, the term “based on” may be understood as not necessarily intended to convey an exclusive set of factors and may, instead, allow for existence of additional factors not necessarily expressly described, again, depending at least in part on context.

It should be readily understood that the meaning of “on,” “above,” and “over” in the present disclosure should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something).

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the term “layer” refers to a material portion including a region with a thickness. A layer can extend over the entirety of an underlying or overlying structure or may have an extent less than the extent of an underlying or overlying structure. Further, a layer can be a region of a homogeneous or inhomogeneous continuous structure that has a thickness less than the thickness of the continuous structure. For example, a layer can be located between any pair of horizontal planes between, or at, a top surface and a bottom surface of the continuous structure. A layer can extend horizontally, vertically, and/or along a tapered surface. A substrate can be a layer, can include one or more layers therein, and/or can have one or more layer thereupon, thereabove, and/or therebelow. A layer can include multiple layers. For example, an interconnect layer can include one or more conductor and contact layers (in which interconnect lines and/or via contacts are formed) and one or more dielectric layers.

As used herein, the term “substrate” refers to a material onto which subsequent material layers are added. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically non-conductive material, such as a glass, a plastic, or a sapphire wafer.

Implementations of the present disclosure can provide one or more of the following technical advantages and/or benefits. For example, a memory device can include multiple memory dice or memory chips stacked in the vertical direction. The multiple memory chips are bonded together using the direct or hybrid bonding technology. In some implementations, the HBM may use the through silicon via (TSV) and u-bump technology to achieve the die-to-wafer bonding or die-to-die bonding. However, the TSV process has a great technological difficulty.

To address one or more of the aforementioned issues, the present disclosure introduces a semiconductor structure based on vertical transistors. By directly connecting the memory periphery area with the contact structure, the power transition can be improved. Furthermore, by pre-removing the substrate in the TSV area, the technological difficulty of forming TSV can be reduced.

The techniques can be applied to various types of semiconductor devices, volatile memory devices, such as DRAM memory devices, or non-volatile memory (NVM) devices, such as NAND flash memory, NOR flash memory, resistive random-access memory (RRAM), phase-change memory (PCM) such as phase-change random-access memory (PCRAM), spin-transfer torque (STT)-Magnetoresistive random-access memory (MRAM), among others. The techniques can also be applied to charge-trapping based memory devices, e.g., silicon-oxide-nitride-oxide-silicon (SONOS) memory devices, and floating-gate based memory devices. The techniques can be applied to three-dimensional (3D) memory devices. The techniques can be applied to various memory types, such as SLC (single-level cell) devices, MLC (multi-level cell) devices like 2-level cell devices, TLC (triple-level cell) devices, QLC (quad-level cell) devices, or PLC (penta-level cell) devices. Additionally or alternatively, the techniques can be applied to various types of devices and systems, such as secure digital (SD) cards, embedded multimedia cards (eMMC), or solid-state drives (SSDs), embedded systems, among others.

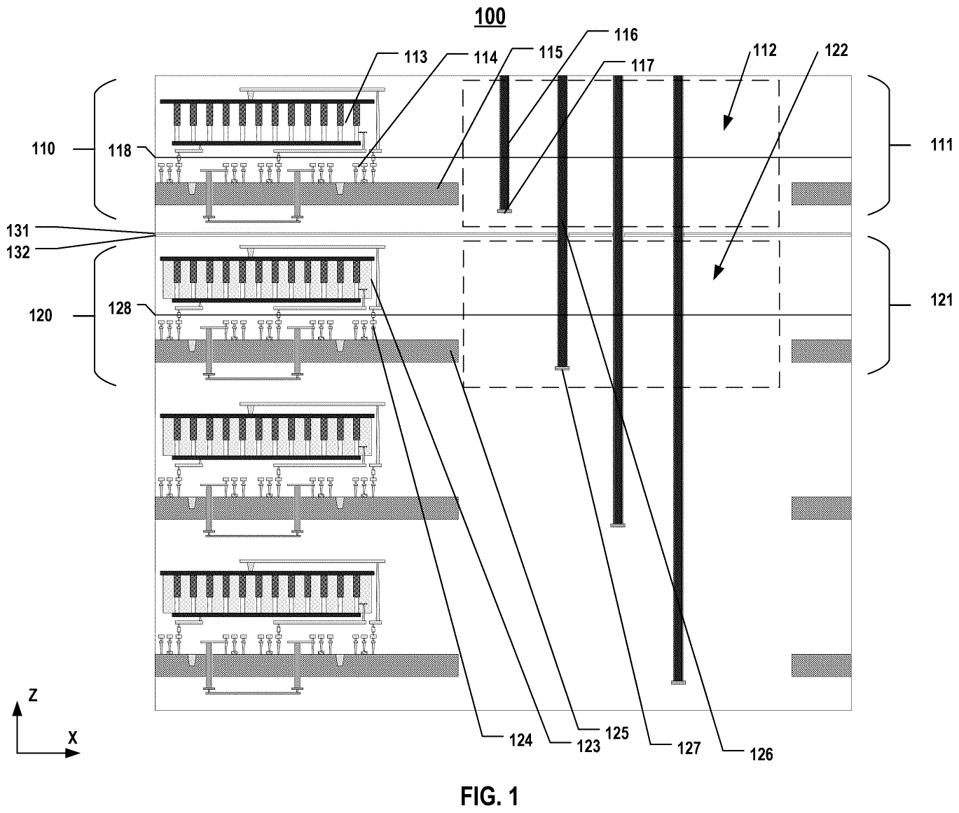

FIG. 1 illustrates a schematic view of a cross-section of a memory device 100, according to some implementations of the present disclosure. The memory device 100 includes a first semiconductor chip 110 and a second semiconductor chip 120 stacking with the first semiconductor chip 110 along the Z-direction. It is noted that more semiconductor chips may be stacked with the first semiconductor chip 110 and the second semiconductor chip 120, as shown in FIG. 1, and the first semiconductor chip 110 and the second semiconductor chip 120 are used to explain the application here.

The first semiconductor chip 110 includes a first semiconductor structure 111 and a first dielectric layer 112 penetrating the first semiconductor structure 111. The second semiconductor chip 120 includes a second semiconductor structure 121 and a second dielectric layer 122 penetrating the second semiconductor structure. In some implementations, the first semiconductor structure 111 and the second semiconductor structure 121 are memory structures. In some implementations, the first semiconductor structure 111 includes a first memory structure 113 and a first periphery structure 114 stacking in the Z-direction. In some implementations, the first periphery structure 114 is formed on a first substrate 115. In some implementations, the first substrate 115 is a silicon substrate. In some implementations, the second semiconductor structure 121 includes a second memory structure 123 and a second periphery structure 124 stacking in the Z-direction. In some implementations, the second periphery structure 124 is formed on a second substrate 125. In some implementations, the second substrate 125 is a silicon substrate. For ease of description, the first dielectric layer 112 and the second dielectric layer 122 are shown in dash lines in FIG. 1, and the first dielectric layer 112 and the second dielectric layer 122 may be formed by the same material of dielectric portions of the first semiconductor structure 111 and the second semiconductor structure 121.

A first contact structure 116 extends along the Z-direction in the first dielectric layer 112 and is in contact with a first metal layer 117 of the first semiconductor chip 110. A second contact structure 126 extends along the Z-direction in the first dielectric layer 112 and the second dielectric layer 122 and is in contact with a second metal layer 127 of the second semiconductor chip 120. The first dielectric layer 112 and the second dielectric layer 122 are aligned in the Z-direction. In some implementations, the first metal layer 117 and the second metal layer 127 extend along the X-direction perpendicular to the Z-direction. In some implementations, the first metal layer 117 is formed below the first substrate 115, and the second metal layer 127 is formed below the second substrate 125, as shown in FIG. 1. In some implementations, the first metal layer 117 is formed above the first substrate 115 and the second metal layer 127 is formed above the second substrate 125.

In some implementations, the first semiconductor chip 110 includes a first dielectric bonding layer 131, the second semiconductor chip 120 includes a second dielectric bonding layer 132, and the first semiconductor chip 110 and the second semiconductor chip 120 are bonded through the first dielectric bonding layer 131 and the second dielectric bonding layer 132. In other words, the first semiconductor chip 110 and the second semiconductor chip 120 are bonded through only the dielectric bonding layers 131 and 132, and no metal structure or metal contact is used for bonding the first semiconductor chip 110 and the second semiconductor chip 120. In some implementations, only silicon oxide is used for bonding the first semiconductor chip 110 and the second semiconductor chip 120. It is noted that, after the bonding operation, since the dielectric bonding layers 131 and 132 are both formed by silicon oxide, the boundary may not be found or may not be obvious in the final product.

In some implementations, the first memory structure 113 is bonded to the first periphery structure 114 through a hybrid bonding layer 118. In some implementations, the hybrid bonding layer 118 includes a dielectric bonding layer and a conductive bonding structure. In other words, the first memory structure 113 is bonded to the first periphery structure 114 through both dielectric material and conductive material. In some implementations, the second memory structure 123 is bonded to the second periphery structure 124 through a hybrid bonding layer 128. In some implementations, the hybrid bonding layer 128 includes a dielectric bonding layer and a conductive bonding structure. In other words, the second memory structure 123 is bonded to the second periphery structure 124 through both dielectric material and conductive material.

The first contact structure 116 extends along the Z-direction in the first dielectric layer 112 and in contact with the first metal layer 117. The second contact structure 126 extends along the Z-direction in both the first dielectric layer 112 and the second dielectric layer 122 and in contact with the second metal layer 127. In some implementations, the first contact structure 116 and the second contact structure 126 are arranged side-by-side along the X-direction, as shown in FIG. 1. In some implementations, the length of the second contact structure 126 in the Z-direction is greater than the length of the first contact structure 116 in the Z-direction.

In some implementations, a top end of the first contact structure 116 and a top end of the second contact structure 126 are coplanar in the X-direction. In other words, the top end of the first contact structure 116 and the top end of the second contact structure 126 both extend to the top surface of the first semiconductor chip 110. Because a planarization operation is performed on the top surface of the first semiconductor chip 110, the top end of the first contact structure 116 and the top end of the second contact structure 126 are coplanar in the X-direction. In some implementations, the bottom end of the first contact structure 116 is in contact with the first metal layer 117, and the bottom end of the second contact structure 126 is in contact with the second metal layer 127.

In some implementations, the first metal layer 117 may be directly connected to the memory periphery area, e.g., the first periphery structure 114. In some implementations, the first metal layer 117 and the metal layer of the first periphery structure 114 may be formed by the same operation. In some implementations, the second metal layer 127 may be directly connected to the memory periphery area, e.g., the second periphery structure 124. In some implementations, the second metal layer 127 and the metal layer of the second periphery structure 124 may be formed by the same operation.

The first semiconductor structure 111 includes the first substrate 115, and the first dielectric layer 112 penetrates the first substrate 115 along the Z-direction. The second semiconductor structure 121 includes the second substrate 125, and the second dielectric layer 122 penetrates the second substrate 125 along the Z-direction. In some implementations, the first contact structure 116 may include a first conductive layer extending in the Z-direction and a first glue layer covering the first conductive layer. In some implementations, the second contact structure 126 may include a second conductive layer extending in the Z-direction and a second glue layer covering the second conductive layer.

By directly connecting the memory periphery area with the contact structure, the power transition can be improved. Furthermore, by pre-removing the substrate in the TSV area, the technological difficulty of forming TSV can be reduced.

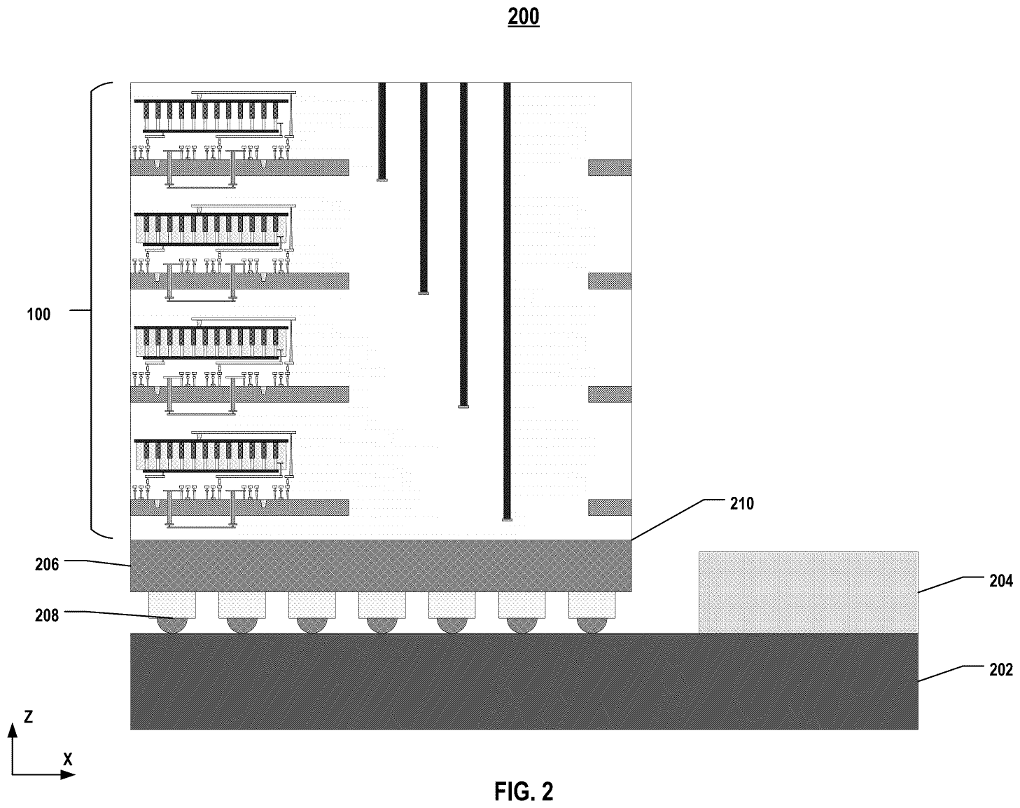

FIG. 2 illustrates a schematic diagram of a memory system 200, according to some aspects of the present disclosure. The memory system 200 includes an interposer 202, a memory device 100 disposed on the interposer 202, a base die 206 disposed between the interposer 202 and the memory device 100, and a computing die 204 disposed on the interposer 202. In some implementations, the base die 206 is configured to control the memory device 100, and the base die 206, and the computing die 204 are integrated on the interposer 202 along the X-direction perpendicular to the Z-direction. The memory device 100 includes the first semiconductor chip 110 and the second semiconductor chip 120 stacking with the first semiconductor chip 110 along the Z-direction, as shown in FIG. 1.

The first semiconductor chip 110 includes the first semiconductor structure 111 and the first dielectric layer 112 penetrating the first semiconductor structure 111. The second semiconductor chip 120 includes the second semiconductor structure 121 and the second dielectric layer 122 penetrating the second semiconductor structure. In some implementations, the first semiconductor structure 111 and the second semiconductor structure 121 are memory structures. In some implementations, the first semiconductor structure 111 includes the first memory structure 113 and the first periphery structure 114 stacking in the Z-direction. In some implementations, the first periphery structure 114 is formed on the first substrate 115. In some implementations, the first substrate 115 is a silicon substrate. In some implementations, the second semiconductor structure 121 includes the second memory structure 123 and the second periphery structure 124 stacking in the Z-direction. In some implementations, the second periphery structure 124 is formed on the second substrate 125. In some implementations, the second substrate 125 is a silicon substrate.

The first contact structure 116 extends along the Z-direction in the first dielectric layer 112 and is in contact with first metal layer 117 of the first semiconductor chip 110. The second contact structure 126 extends along the Z-direction in the first dielectric layer 112 and the second dielectric layer 122 and is in contact with the second metal layer 127 of the second semiconductor chip 120. The first dielectric layer 112 and the second dielectric layer 122 are aligned in the Z-direction. In other words, from the plane view of the memory device 100, the first dielectric layer 112 and the second dielectric layer 122 may be partially overlapped or fully overlapped.

In some implementations, the first metal layer 117 and the second metal layer 127 extend along the X-direction perpendicular to the Z-direction. In some implementations, the first metal layer 117 is formed below the first substrate 115, and the second metal layer 127 is formed below the second substrate 125, as shown in FIG. 1. In some implementations, the first metal layer 117 is formed above the first substrate 115 and the second metal layer 127 is formed above the second substrate 125.

As shown in FIG. 2, the semiconductor chips and the base die 206 are stacked (e.g., sequentially) along the Z-direction. The base die 206 and the computing die 204 are integrated on different positions of the interposer 202 along the X-direction. In some implementations, the first semiconductor chip 110 and the second semiconductor chip 120, and more semiconductor chips may be boned to the base die 206 through a bonding layer 210. In some implementations, the bonding layer 210 may be a direct bonding layer including at least one dielectric material and exclude a conductive bonding contact. In some implementations, the bonding layer 210 may be a hybrid bonding layer including bonding contacts and at least one dielectric material isolating the bonding contacts. In some implementations, the bonding contacts of the bonding layer 210 may further connect the interconnect layers or redistribution layers of the memory device 100.

In some implementations, the base die 206 includes a control circuitry that is configured to control the memory device 100. The base die 206 is bonded to the interposer 202 through a plurality of bump structures 208. The base die 206 may be coupled to the computing die 204 through the interposer 202. The interposer 202 may have the conductive terminals and the wirings internally formed in the interposer 202, and the base die 206 may be coupled to the computing die 204 through the conductive terminals and the internal wirings of the interposer 202. It is understood that in practice, the base die 206, the computing die 204, and the interposer 202 can be integrated together using any suitable packaging technology including, for example, Chip-on-Wafer-on-Substrate (CoWoS).

By directly connecting the memory periphery area with the contact structure, the power transition can be improved. Furthermore, by pre-removing the substrate in the TSV area, the technological difficulty of forming TSV can be reduced.

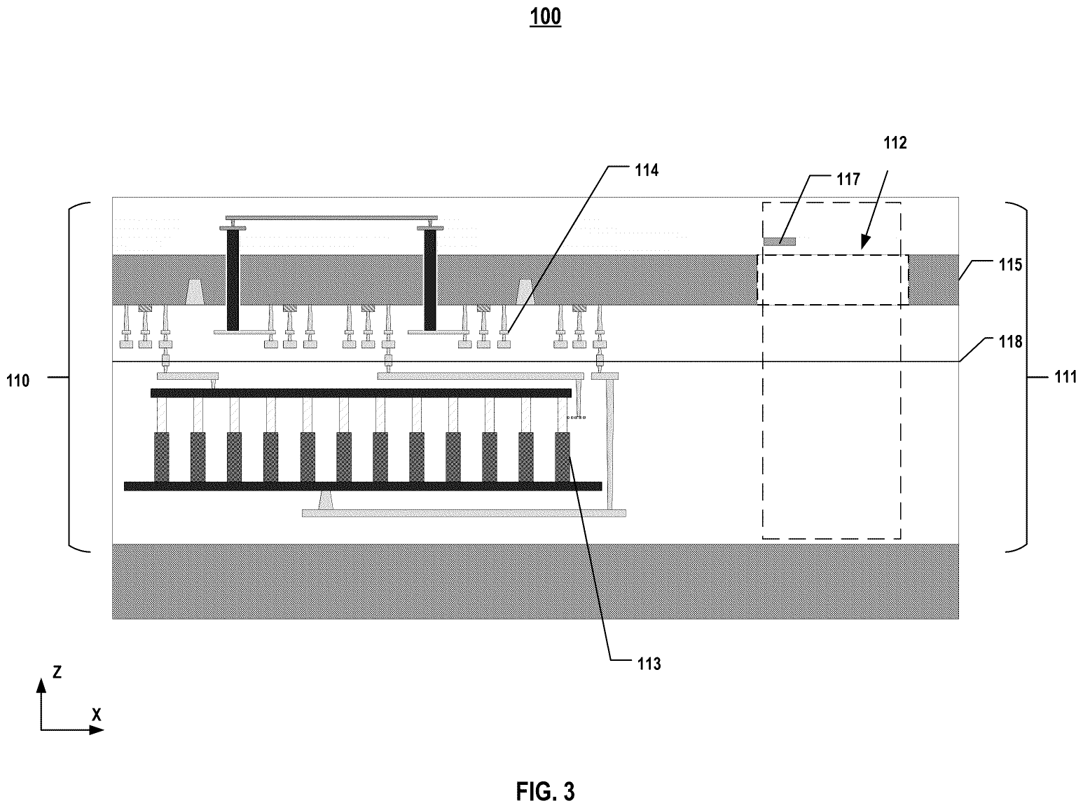

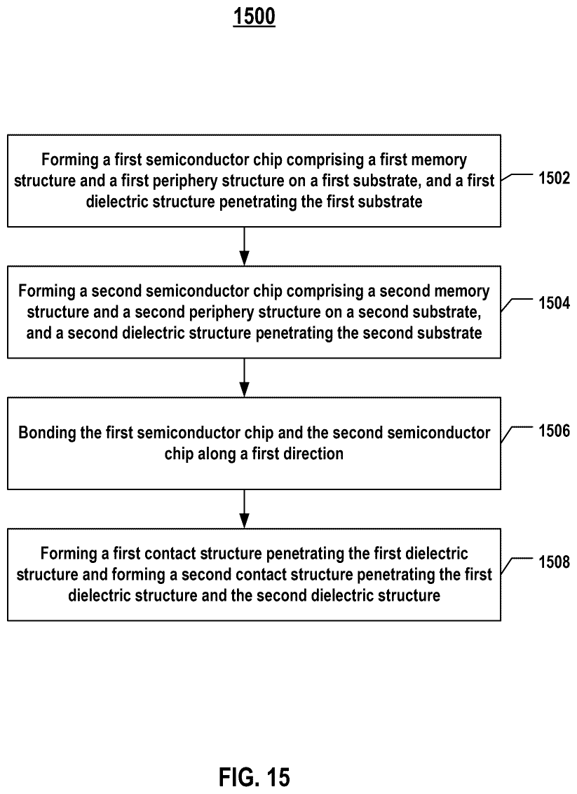

FIGS. 3-14 illustrate cross-sectional views of the memory device 100 at various stages of a fabrication process, according to some implementations of the present disclosure. FIG. 15 illustrates a flowchart of a method 1500 for forming the memory device 100, according to some implementations of the present disclosure. For the purpose of better describing the present disclosure, the memory device 100 in FIGS. 3-14 and the method 1500 in FIG. 15 will be discussed together. It is understood that the operations shown in the method 1500 are not exhaustive and that other operations may be performed as well before, after, or between any of the illustrated operations. Further, some of the operations may be performed simultaneously, or in a different order than shown in FIGS. 3-14 and FIG. 15.

As shown in FIG. 3 and operation 1502 of FIG. 15, a first semiconductor chip 110 is formed on the first substrate 115. The first semiconductor chip 110 includes the first memory structure 113 and the first periphery structure 114. The first dielectric layer 112 is formed, penetrating the first substrate 115.

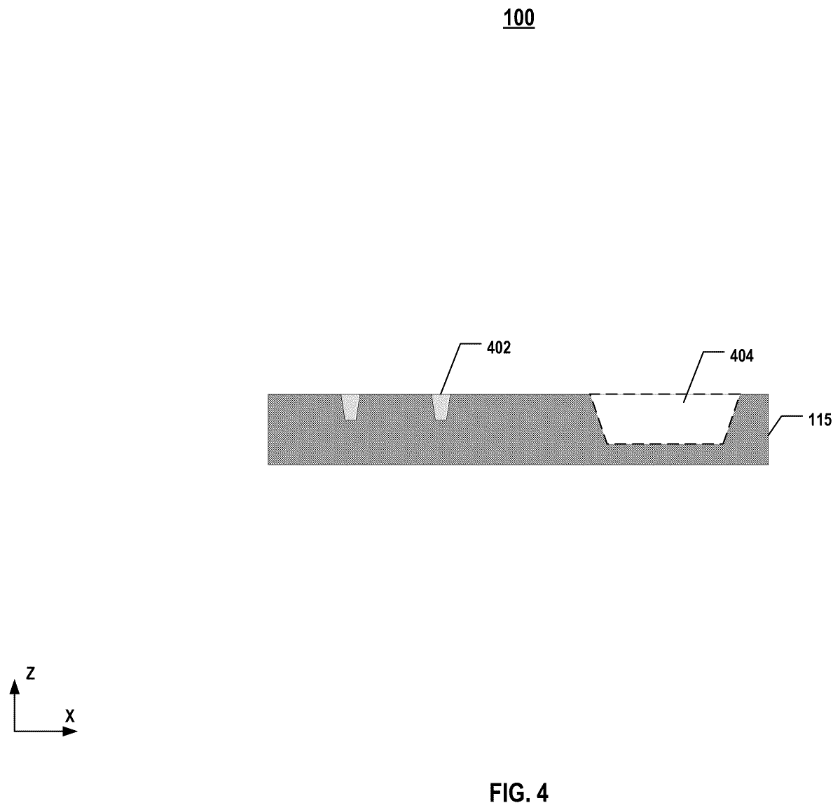

As shown in FIG. 4, a dielectric structure 404 and a shallow trench isolation (STI) structure 402 are formed on the first side of the first substrate 115. In some implementations, an etch operation is performed on the first side of the first substrate 115 to form a trench and an opening. Then, a deposition operation is performed to form the dielectric material in the trench as the STI structure 402 and in the opening as the dielectric structure 404. In some implementations, a planarization operation may be performed on the top surface of the dielectric structure 404, the STI structure 402, and the first side (the top side in FIG. 4) of the first substrate 115.

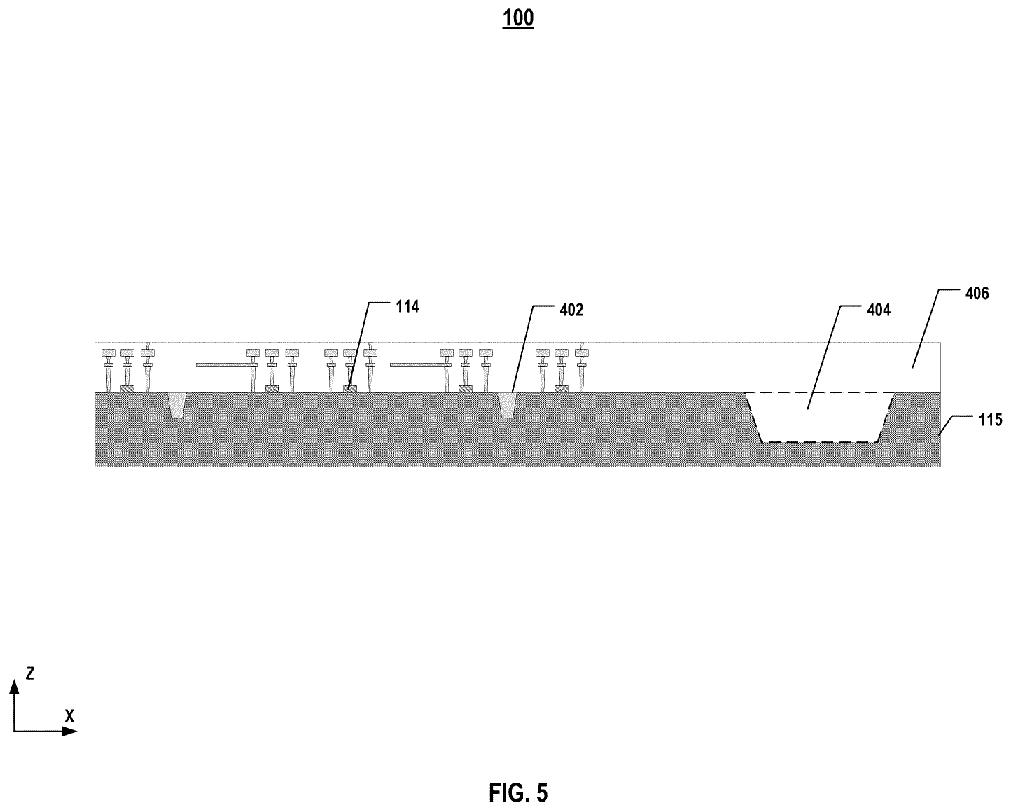

As shown in FIG. 5, the first periphery structure 114 is formed on the first side of the first substrate 115. In some implementations, the first periphery structure 114 may include any suitable digital, analog, and/or mixed-signal peripheral circuits used for facilitating the operation of the first memory structure 113, such as page buffers, decoders, and latches. In some implementations, the first periphery structure 114 includes a dielectric layer 406 formed on the dielectric structure 404, the STI structure 402, and the first side of the first substrate 115. In some implementations, the dielectric layer 406 and the dielectric structure 404 are formed by the same dielectric material. In some implementations, the dielectric layer 406 and the dielectric structure 404 are formed by silicon oxide.

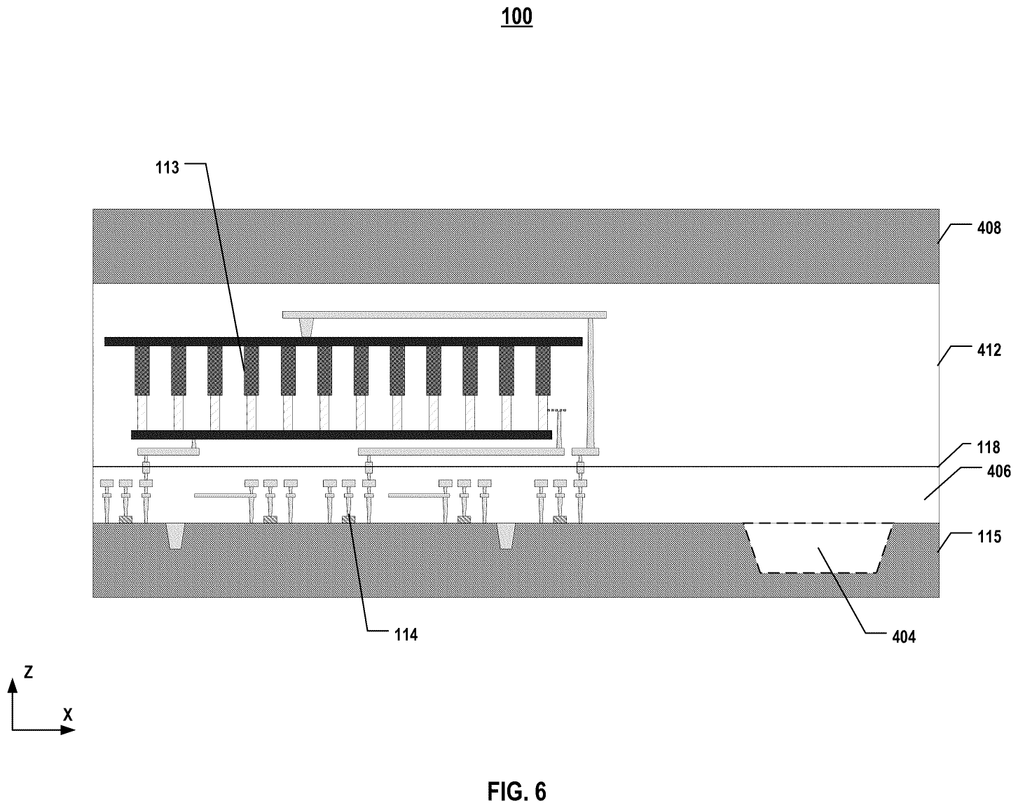

As shown in FIG. 6, the first memory structure 113 is formed on a substrate 408, and the first memory structure 113 includes a dielectric layer 412. The first memory structure 113 and the substrate 408 are flipped and bonded on the first periphery structure 114. In some implementations, the first memory structure 113 and the first periphery structure 114 are bonded through the hybrid bonding layer 118. In some implementations, the hybrid bonding layer 118 includes a dielectric bonding layer and a conductive bonding structure. In other words, the first memory structure 113 is bonded to the first periphery structure 114 through both dielectric material and conductive material. In some implementations, the hybrid bonding layer 118 includes dielectric-to-dielectric bonding layer and metal-to-metal bonding layer.

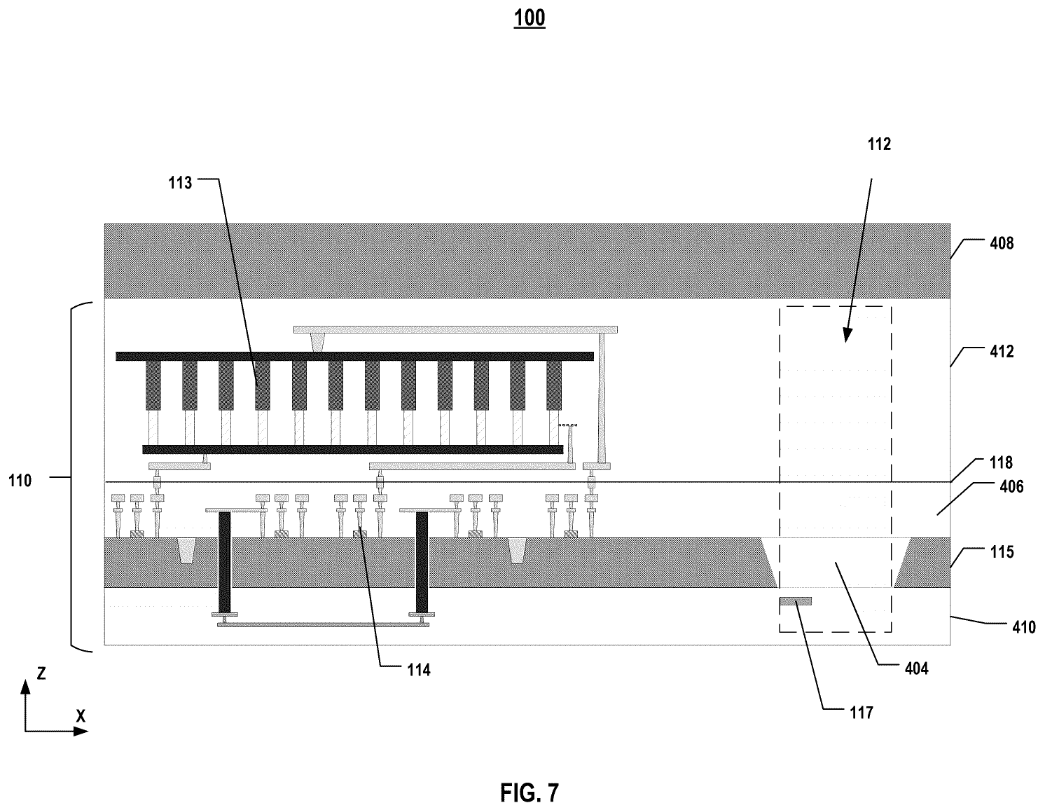

As shown in FIG. 7, a thinning operation is performed on the second side (the bottom side in FIG. 7) of the first substrate 115 to expose the dielectric structure 404. Then, the interconnect structures of the first periphery structure 114 are formed on the second side of the first substrate 115. In some implementations, the first metal layer 117 is also formed on the second side of the first substrate 115. In some implementations, the first metal layer 117 extends in the X-direction. In some implementations, the first metal layer 117 may be formed with the interconnect structures of the first periphery structure 114 together. A dielectric layer 410 is formed to cover the dielectric structure 404, the first metal layer 117, and the interconnect structures of the first periphery structure 114.

Then, the first semiconductor chip 110 is formed including the first memory structure 113 and the first periphery structure 114, and the first dielectric layer 112 is formed penetrating the first substrate 115. The first dielectric layer 112, as shown in dash lines in FIG. 7, includes portions of the dielectric layer 412 of the first memory structure 113, the dielectric layer 406 of the first periphery structure 114, the dielectric structure 404, and the dielectric layer 410 of the first periphery structure 114.

It is noted that the dielectric layer 412 of the first memory structure 113, the dielectric layer 406 of the first periphery structure 114, the dielectric structure 404, and the dielectric layer 410 of the first periphery structure 114 may be formed by the same material. In some implementations, the dielectric layer 412 of the first memory structure 113, the dielectric layer 406 of the first periphery structure 114, the dielectric structure 404, and the dielectric layer 410 of the first periphery structure 114 are formed by silicon oxide. In some implementations, because the dielectric layer 412, the dielectric layer 406, the dielectric structure 404, and the dielectric layer 410 are formed by the same material, the area of the first dielectric layer 112 may not be obvious in the final product. The dash line showing the area of the first dielectric layer 112 is for the purpose of explaining the current application, not for limiting. As shown in FIG. 7, the first dielectric layer 112 penetrates the first memory structure 113, the first periphery structure 114, and the first substrate 115.

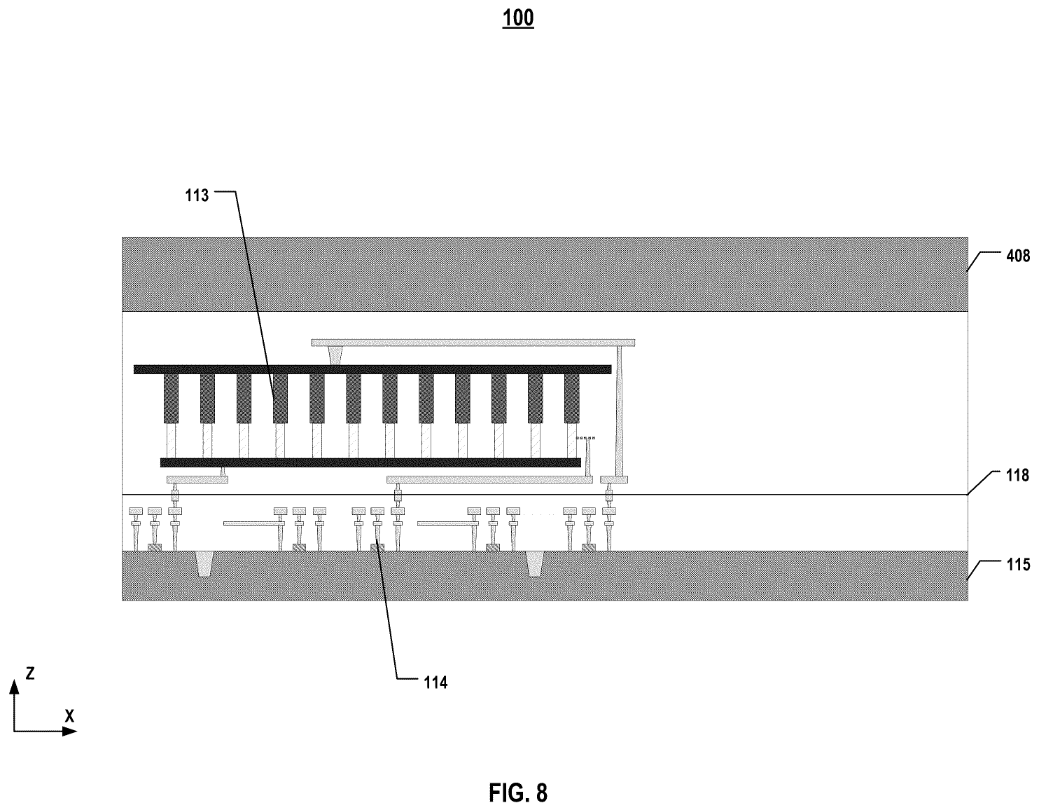

FIGS. 8-10 illustrate another implementation to form the memory device 100 shown in FIG. 3. As shown in FIG. 8, the first periphery structure 114 is formed on the first side of the first substrate 115, and the first memory structure 113 is formed on the substrate 408. Then, the first memory structure 113 and the substrate 408 are flipped and bonded on the first periphery structure 114. In some implementations, the first memory structure 113 and the first periphery structure 114 are bonded through the hybrid bonding layer 118. In some implementations, the hybrid bonding layer 118 includes a dielectric bonding layer and a conductive bonding structure. In other words, the first memory structure 113 is bonded to the first periphery structure 114 through both dielectric material and conductive material. In some implementations, the hybrid bonding layer 118 includes dielectric-to-dielectric bonding layer and metal-to-metal bonding layer.

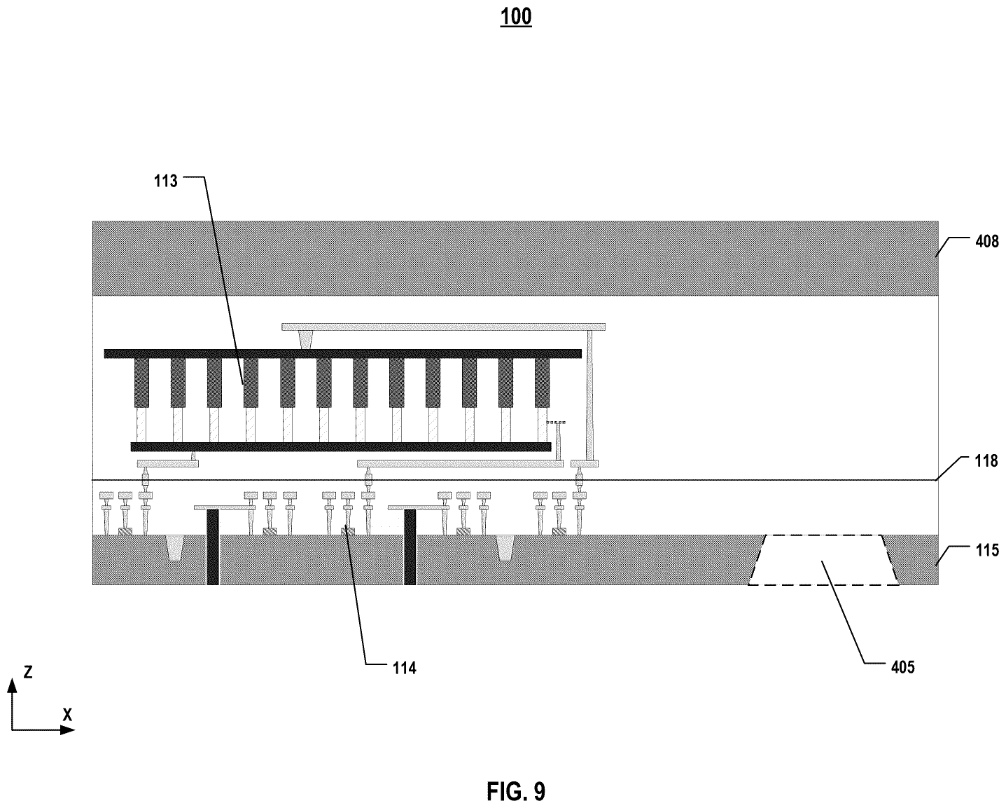

As shown in FIG. 9, a thinning operation is performed on the second side (the bottom side in FIG. 9) of the first substrate 115. Then, an etch operation is performed on the second side of the first substrate 115 to form an opening, and a deposition operation is performed to form a dielectric structure 405 in the opening. In some implementations, the etch operation performed on the second side of the first substrate 115 penetrates the first substrate 115, and therefore the dielectric structure 405 penetrates the first substrate 115.

Comparing the dielectric structure 404 formed in the first substrate 115 in FIG. 6 and the dielectric structure 405 formed in the first substrate 115 in FIG. 9, the dielectric structure 404 and the dielectric structure 405 may have different shapes. In some implementations, since the dielectric structure 404 is formed from the first side of the first substrate 115, the upper portion of the dielectric structure 404 is wider than the bottom portion of the dielectric structure 404. In some implementations, since the dielectric structure 405 is formed from the second side of the first substrate 115, the bottom portion of the dielectric structure 405 is wider than the upper portion of the dielectric structure 405.

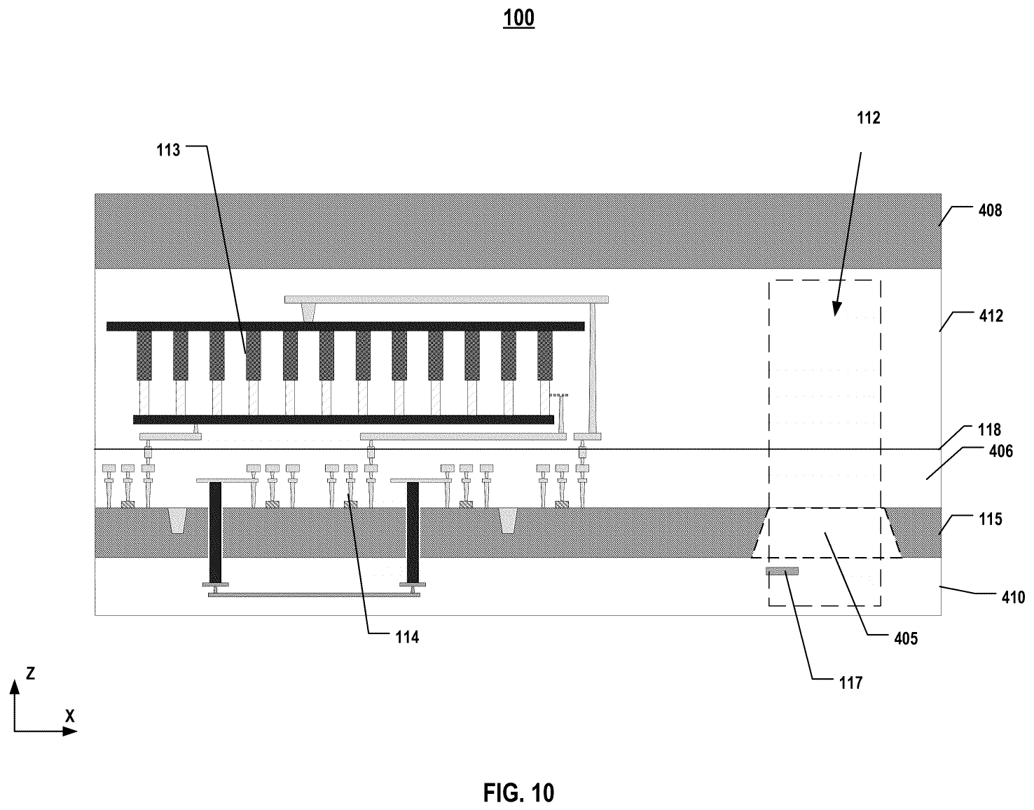

As shown in FIG. 10, the interconnect structures of the first periphery structure 114 are formed on the second side of the first substrate 115. In some implementations, the first metal layer 117 is also formed on the second side of the first substrate 115. In some implementations, the first metal layer 117 extends in the X-direction. In some implementations, the first metal layer 117 may be formed with the interconnect structures of the first periphery structure 114 together. The dielectric layer 410 is formed to cover the dielectric structure 405, the first metal layer 117, and the interconnect structures of the first periphery structure 114.

Then, the first semiconductor chip 110 is formed including the first memory structure 113 and the first periphery structure 114, and the first dielectric layer 112 is formed penetrating the first substrate 115. The first dielectric layer 112, as shown in dash lines in FIG. 10, includes portions of the dielectric layer 412 of the first memory structure 113, the dielectric layer 406 of the first periphery structure 114, the dielectric structure 405, and the dielectric layer 410 of the first periphery structure 114.

It is noted that the dielectric layer 412 of the first memory structure 113, the dielectric layer 406 of the first periphery structure 114, the dielectric structure 405, and the dielectric layer 410 of the first periphery structure 114 may be formed by the same material. In some implementations, the dielectric layer 412 of the first memory structure 113, the dielectric layer 406 of the first periphery structure 114, the dielectric structure 405, and the dielectric layer 410 of the first periphery structure 114 are formed by silicon oxide. In some implementations, because the dielectric layer 412, the dielectric layer 406, the dielectric structure 405, and the dielectric layer 410 are formed by the same material, the area of the first dielectric layer 112 may not be obvious in the final product. The dash line showing the area of the first dielectric layer 112 is for the purpose of explaining the current application, not for limiting. As shown in FIG. 10, the first dielectric layer 112 penetrates the first memory structure 113, the first periphery structure 114, and the first substrate 115.

As shown in operation 1504 of FIG. 15, a second semiconductor chip 120 is formed on the second substrate 125. The second semiconductor chip 120 includes the second memory structure 123 and the second periphery structure 124. The second dielectric layer 122 is formed, penetrating the second substrate 125. The process of forming the second semiconductor chip 120 may be similar to the process of forming the first semiconductor chip 110 shown in FIGS. 3-10, so that will not be repeated here.

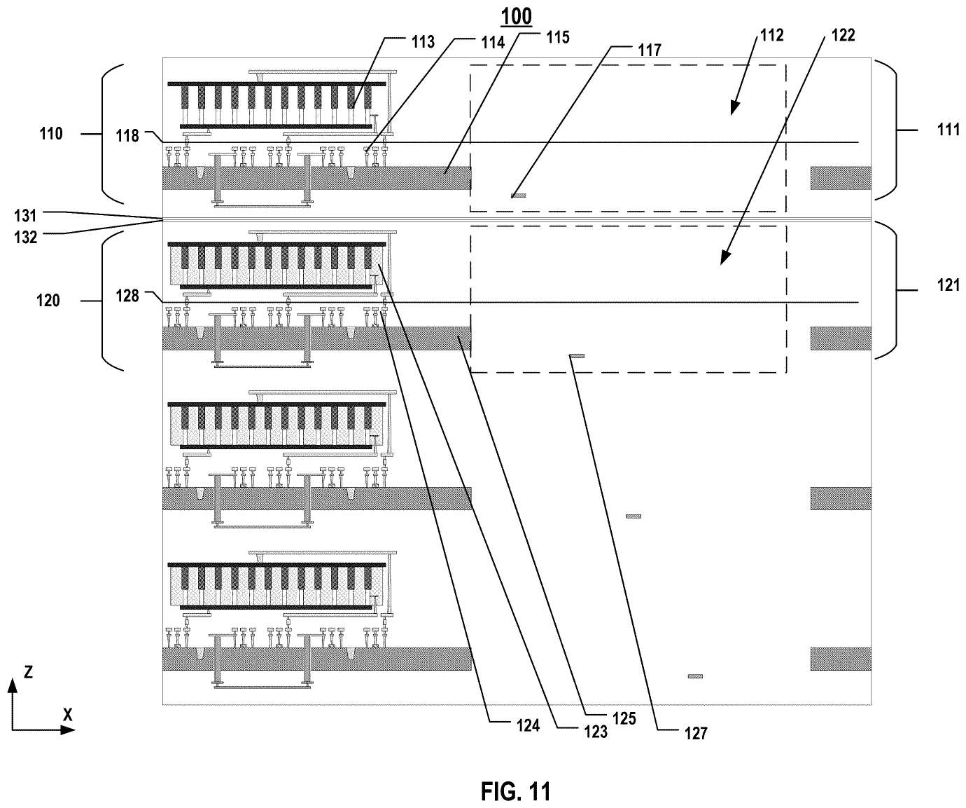

As shown in FIG. 11 and operation 1506 of FIG. 15, the first semiconductor chip 110 and the second semiconductor chip 120 are bonded along the Z-direction. In some implementations, the first semiconductor chip 110 and the second semiconductor chip 120 are bonded through a direct dielectric-to-dielectric bonding. In some implementations, the first semiconductor chip 110 and the second semiconductor chip 120 are bonded through the first dielectric bonding layer 131 and the second dielectric bonding layer 132. In some implementations, after bonding the first semiconductor chip 110 and the second semiconductor chip 120, the first dielectric layer 112 and the second dielectric layer 122 are aligned in the Z-direction. In some implementations, after bonding the first semiconductor chip 110 and the second semiconductor chip 120, the first metal layer 117 and the second metal layer 127 are misaligned in the Z-direction.

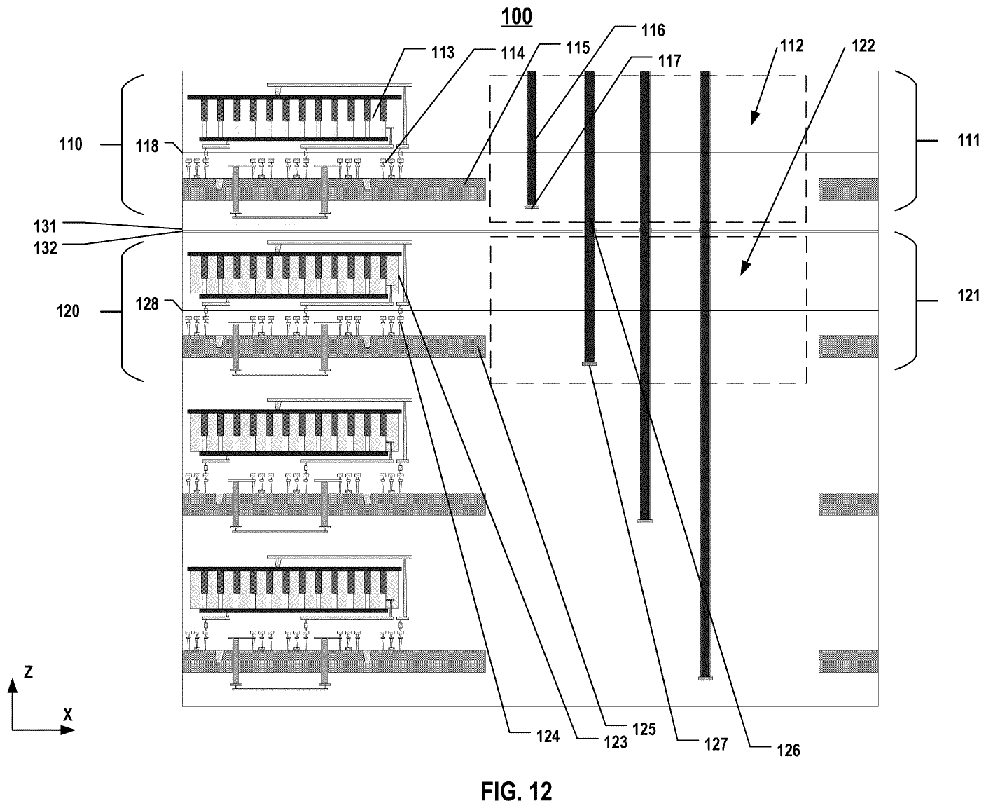

As shown in FIG. 12 and operation 1508 of FIG. 15, a first contact structure 116 is formed penetrating the first dielectric layer 112, and a second contact structure 126 is formed penetrating the first dielectric layer 112 and the second dielectric layer 122. In some implementations, an etching operation is performed to form a first opening penetrating the first dielectric layer 112 to expose the first metal layer 117. In some implementations, an etching operation is performed to form a second opening penetrating the first dielectric layer 112 and the second dielectric layer 122 to expose the second metal layer 127. In some implementations, the first opening and the second opening may be formed in the same etching operation using the first metal layer 117 and the second metal layer 127 as a stop layer. In some implementations, the first opening and the second opening may be formed in multiple etching operations. Then, the first contact structure 116 is formed in the first opening, and the second contact structure 126 is formed in the second opening.

In some implementations, before forming the first contact structure 116 and the second contact structure 126, a first glue layer may be formed on the sidewalls of the first opening, and a second glue layer may be formed on the sidewalls of the second opening. Then, the first contact structure 116 is formed on the first glue layer, and the second contact structure 126 is formed on the second glue layer. The first contact structure 116 is in contact with the first metal layer 117, and the second contact structure 126 is in contact with the second metal layer 127. In some implementations, the first contact structure 116 is in direct contact with the first metal layer 117, and the second contact structure 126 is in direct contact with the second metal layer 127. In some implementations, after forming the first contact structure 116 and the second contact structure 126, a planarization operation may be performed on the top surface of the first memory structure 113.

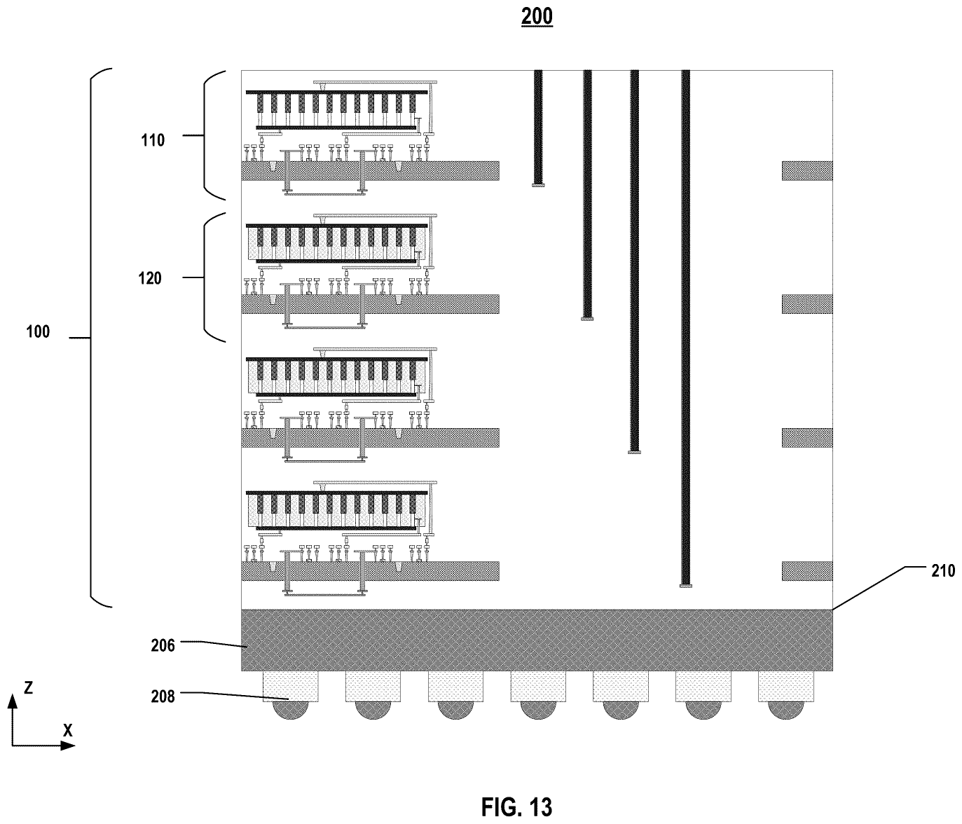

As shown in FIG. 13, the memory device 100, including the first semiconductor chip 110 and the second semiconductor chip 120, is bonded to the base die 206 through the bonding layer 210. In some implementations, the bonding layer 210 may be a direct bonding layer including at least one dielectric material and exclude a conductive bonding contact. In some implementations, the bonding layer 210 may be a hybrid bonding layer including bonding contacts and at least one dielectric material isolating the bonding contacts. In some implementations, the bonding contacts of the bonding layer 210 may further connect the interconnect layers or redistribution layers of the memory device 100.

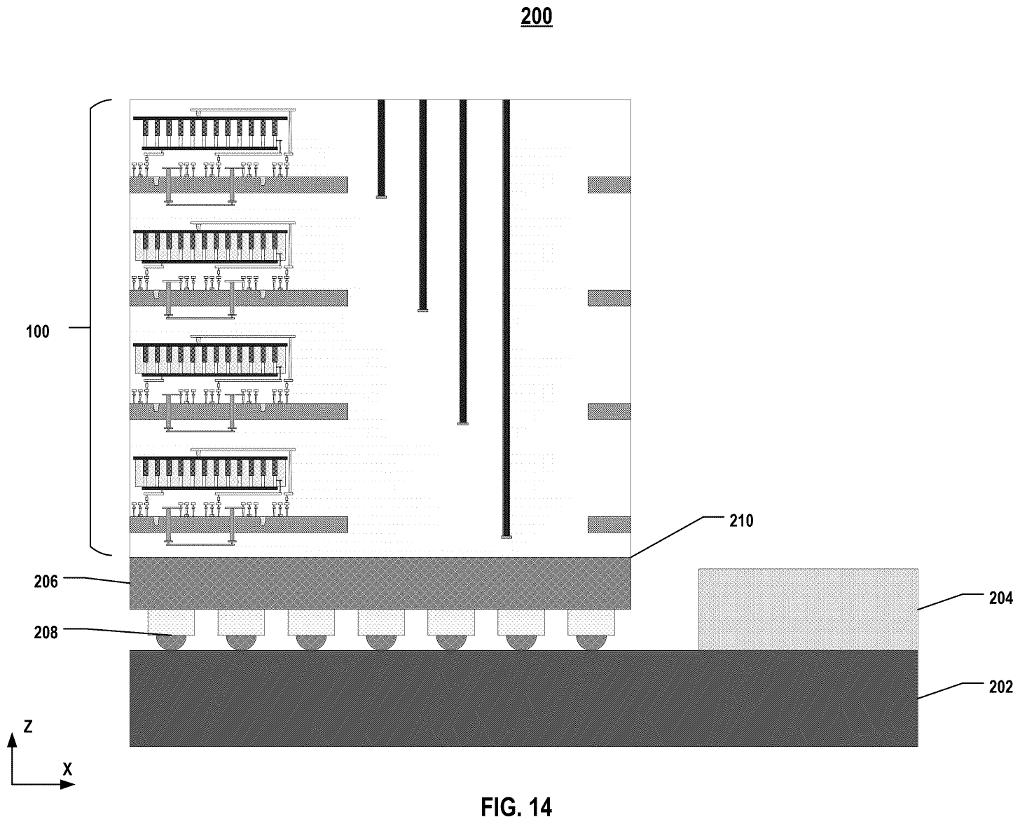

As shown in FIG. 14, the base die 206 and the computing die 204 are bonded to the interposer 202. In some implementations, the base die 206 is configured to control the memory device 100, and the base die 206 and the computing die 204 are integrated on the interposer 202 along the X-direction perpendicular to the Z-direction.

By directly connecting the memory periphery area with the contact structure, the power transition can be improved. Furthermore, by pre-removing the substrate in the TSV area, the technological difficulty of forming TSV can be reduced.

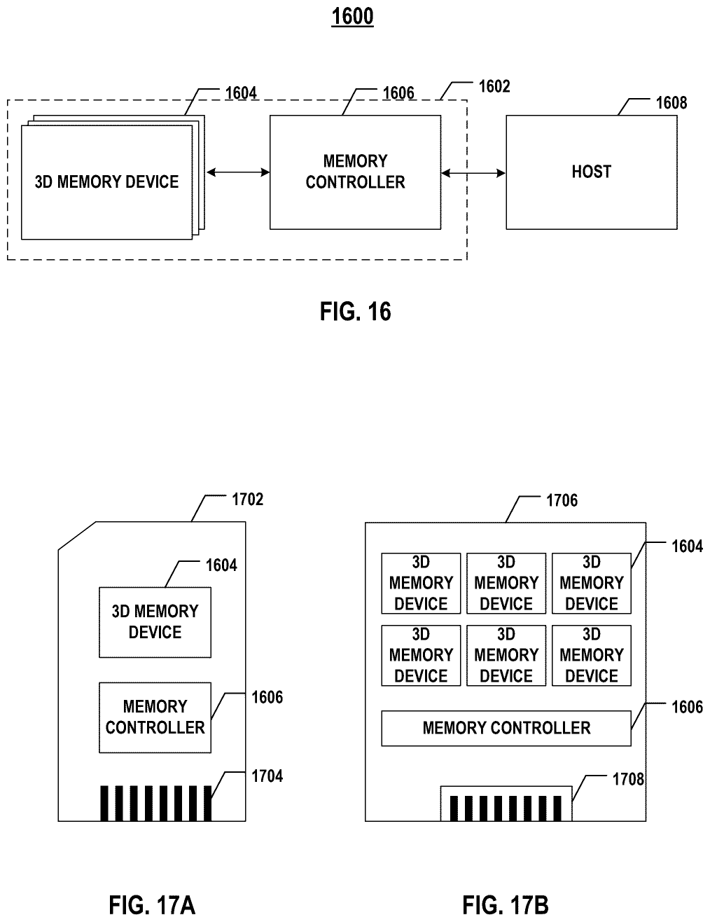

FIG. 16 illustrates a block diagram of a system 1600 having a memory device, according to some aspects of the present disclosure. System 1600 can be a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic devices having storage therein. As shown in FIG. 16, system 1600 can include a host 1608 and a memory system 1602 having one or more memory devices 1604 and a memory controller 1606. Host 1608 can be a processor of an electronic device, such as a central processing unit (CPU), or a system-on-chip (SoC), such as an application processor (AP). Host 1608 can be configured to send or receive the data to or from memory devices 1604.

Memory controller 1606 is coupled to memory device 1604 and host 1608 and is configured to control memory device 1604, according to some implementations. In some implementations, memory device 1604 can be the memory device 100 described above. Memory controller 1606 can manage the data stored in memory device 1604 and communicate with host 1608. In some implementations, memory controller 1606 is designed for operating in a low duty-cycle environment like secure digital (SD) cards, compact Flash (CF) cards, universal serial bus (USB) Flash drives, or other media for use in electronic devices, such as personal computers, digital cameras, mobile phones, etc. In some implementations, memory controller 1606 is designed for operating in a high duty-cycle environment SSDs or embedded multi-media-cards (eMMCs) used as data storage for mobile devices, such as smartphones, tablets, laptop computers, etc., and enterprise storage arrays. Memory controller 1606 can be configured to control operations of memory device 1604, such as read, erase, and program operations. In some implementations, memory controller 1606 is configured to control the array of memory cells through the first peripheral circuit and the second peripheral circuit. Memory controller 1606 can also be configured to manage various functions with respect to the data stored or to be stored in memory device 1604 including, but not limited to bad-block management, garbage collection, logical-to-physical address conversion, wear leveling, etc. In some implementations, memory controller 1606 is further configured to process error correction codes (ECCs) with respect to the data read from or written to memory device 1604. Any other suitable functions may be performed by memory controller 1606 as well, for example, formatting memory device 1604. Memory controller 1606 can communicate with an external device (e.g., host 1608) according to a particular communication protocol. For example, memory controller 1606 may communicate with the external device through at least one of various interface protocols, such as a USB protocol, an MMC protocol, a peripheral component interconnection (PCI) protocol, a PCI-express (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

Memory controller 1606 and one or more memory devices 1604 can be integrated into various types of storage devices, for example, be included in the same package, such as a universal Flash storage (UFS) package or an eMMC package. That is, memory system 1602 can be implemented and packaged into different types of end electronic products. In one example as shown in FIG. 17A, memory controller 1606 and a single memory device 1604 may be integrated into a memory card 1702. Memory card 1702 can include a PC card (PCMCIA, personal computer memory card international association), a CF card, a smart media (SM) card, a memory stick, a multimedia card (MMC, RS-MMC, MMCmicro), an SD card (SD, miniSD, microSD, SDHC), a UFS, etc. Memory card 1702 can further include a memory card connector 1704 coupling memory card 1702 with a host (e.g., host 1608 in FIG. 16). In another example as shown in FIG. 17B, memory controller 1606 and multiple memory devices 1604 may be integrated into an SSD 1706. SSD 1706 can further include an SSD connector 1708 coupling SSD 1706 with a host (e.g., host 1608 in FIG. 16). In some implementations, the storage capacity and/or the operation speed of SSD 1706 is greater than those of memory card 1702.

The foregoing description of the specific implementations can be readily modified and/or adapted for various applications. Therefore, such adaptations and modifications are intended to be within the meaning and range of equivalents of the disclosed implementations, based on the teaching and guidance presented herein.

The breadth and scope of the present disclosure should not be limited by any of the above-described exemplary implementations, but should be defined only in accordance with the following claims and their equivalents.

What is claimed is:

1. A memory device, comprising:
a first semiconductor chip comprising a first semiconductor structure and a first dielectric layer penetrating the first semiconductor structure;
a second semiconductor chip stacking with the first semiconductor chip along a first direction, the second semiconductor chip comprising a second semiconductor structure and a second dielectric layer penetrating the second semiconductor structure;
a first contact structure extending along the first direction in the first dielectric layer and in contact with a first metal layer of the first semiconductor chip; and
a second contact structure extending along the first direction in the first dielectric layer and the second dielectric layer and in contact with a second metal layer of the second semiconductor chip,
wherein the first dielectric layer and the second dielectric layer are aligned in the first direction.

2. The memory device of claim 1, wherein the first semiconductor chip further comprises a first dielectric bonding layer, the second semiconductor chip further comprises a second dielectric bonding layer, and the first semiconductor chip and the second semiconductor chip are bonded through the first dielectric bonding layer and the second dielectric bonding layer.

3. The memory device of claim 1, wherein the first semiconductor structure comprises a first memory structure and a first periphery structure stacking in the first direction.

4. The memory device of claim 3, wherein the first memory structure is bonded to the first periphery structure through a hybrid bonding layer.

5. The memory device of claim 4, wherein the hybrid bonding layer comprises a dielectric bonding layer and a conductive bonding structure.

6. The memory device of claim 1, wherein the first metal layer and the second metal layer extend along a second direction perpendicular to the first direction.

7. The memory device of claim 6, wherein the first contact structure and the second contact structure are arranged side-by-side along the second direction.

8. The memory device of claim 7, wherein a length of the second contact structure in the first direction is greater than a length of the first contact structure in the first direction.

9. The memory device of claim 7, wherein a first end of the first contact structure and a first end of the second contact structure are coplanar in the second direction, a second end of the first contact structure is in contact with the first metal layer, and a second end of the second contact structure is in contact with the second metal layer.

10. The memory device of claim 1, wherein the first semiconductor structure comprises a first substrate and the first dielectric layer penetrates the first substrate along the first direction.

11. The memory device of claim 1, wherein the first contact structure comprises a first conductive layer extending in the first direction and a first glue layer covering the first conductive layer.

12. A system, comprising:
an interposer;
a memory device disposed on the interposer, comprising:
a first semiconductor chip comprising a first semiconductor structure and a first dielectric layer penetrating the first semiconductor structure;
a second semiconductor chip stacking with the first semiconductor chip along a first direction, the second semiconductor chip comprising a second semiconductor structure and a second dielectric layer penetrating the second semiconductor structure;
a first contact structure extending along the first direction in the first dielectric layer and in contact with a first metal layer of the first semiconductor chip; and
a second contact structure extending along the first direction in the first dielectric layer and the second dielectric layer and in contact with a second metal layer of the second semiconductor chip,
wherein the first dielectric layer and the second dielectric layer are aligned in the first direction;
a base die disposed between the interposer and the memory device configured to control the memory device; and
a computing die disposed on the interposer, wherein the base die and the computing die are integrated on the interposer along a second direction perpendicular to the first direction.

13. The system of claim 12, wherein the base die comprises a control circuitry to control the memory device through the first contact structure and the second contact structure.

14. The system of claim 12, wherein the base die and the computing die are bonded to a same surface of the interposer.

15. A method of forming a memory device, comprising:
forming a first semiconductor chip comprising a first memory structure and a first periphery structure on a first substrate, and a first dielectric structure penetrating the first substrate;
forming a second semiconductor chip comprising a second memory structure and a second periphery structure on a second substrate, and a second dielectric structure penetrating the second substrate;
bonding the first semiconductor chip and the second semiconductor chip along a first direction; and
forming a first contact structure penetrating the first dielectric structure and forming a second contact structure penetrating the first dielectric structure and the second dielectric structure.

16. The method of claim 15, further comprising:
bonding the first semiconductor chip and the second semiconductor chip to a base die; and
bonding the base die and a computing die to an interposer.

17. The method of claim 15, wherein forming the first semiconductor chip further comprises forming a first landing layer under the first dielectric structure, and wherein forming the second semiconductor chip further comprises forming a second landing layer under the second dielectric structure.

18. The method of claim 17, wherein forming the first semiconductor chip comprises:
forming the first dielectric structure on a first side of the first substrate;
forming the first periphery structure on the first side of the first substrate;
forming the first memory structure on a third substrate;
bonding the first periphery structure and the first memory structure; and
performing a thinning operation on a second side of the first substrate opposite to the first side to expose the first dielectric structure.

19. The method of claim 15, wherein bonding the first semiconductor chip and the second semiconductor chip comprises:
bonding the first semiconductor chip and the second semiconductor chip through a direct dielectric-to-dielectric bonding.

20. The method of claim 15, wherein bonding the first semiconductor chip and the second semiconductor chip comprises:
bonding the first semiconductor chip and the second semiconductor chip to have the first dielectric structure and the second dielectric structure aligned in the first direction.
